(19) United States
(12) Patent Application Publication
(10) Pub. No.: US 2013/0140529 A1
(43) Pub. Date: Jun. 6, 2013

(54) ORGANIC LIGHT EMITTING DEVICE CAPABLE OF REDUCING LEAKAGE CURRENT BETWEEN PIXELS

(71) Applicants: Ju-Yeop Seong, Cheonan-si (KR); Jae-Hoon Hwang, Seoul (KR); Jae-Hyun Kim, Asan-si (KR); Jae-Young Lee, Yongin-si (KR); Chul-Hwan Park, Asan-si (KR); Chang-Woo Shim, Asan-si (KR); Sola Lee, Seoul (KR)

(72) Inventors: Ju-Yeop Seong, Cheonan-si (KR); Jae-Hoon Hwang, Seoul (KR); Jae-Hyun Kim, Asan-si (KR); Jae-Young Lee, Yongin-si (KR); Chul-Hwan Park, Asan-si (KR); Chang-Woo Shim, Asan-si (KR); Sola Lee, Seoul (KR)

(73) Assignee: SAMSUNG MOBILE DISPLAY CO., LTD., Yongin-City (KR)

(21) Appl. No.: 13/538,381

(22) Filed: Jun. 29, 2012

(30) Foreign Application Priority Data
Dec. 1, 2011 (KR) 10-2011-0127908

(51) Int. Cl. H01L 27/32; H01L 51/56

(52) U.S. Cl. 257/40; 438/34; 257/E27.119; 257/E51.018

(57) ABSTRACT

Disclosed is an organic light emitting device having an improved light emitting quality, by which a leakage current generated between pixels when a current flows from one pixel to an adjacent pixel of a light emitting part may be prevented, making it possible to prevent undesired emission of light in the adjacent pixel and improve light emitting quality.

### CLAIM OF PRIORITY

This application makes reference to, incorporates the same herein, and claims all benefits accruing under 35 U.S.C. §119 from an application earlier filed in the Korean Intellectual Property Office on 1 Dec. 2011 and there duly assigned Serial No. 10-2011-0127908.

### BACKGROUND OF THE INVENTION

1. Field of the Invention

An embodiment of the present invention relates to an organic light emitting device, more particularly, to an organic light emitting device having an improved light emitting quality, by which a leakage current generated between pixels when a current flows from one pixel to an adjacent pixel of a light emitting part may be prevented, making it possible to prevent undesired emission of light in the adjacent pixel and to improve light emitting quality.

2. Description of the Related Art

In recent years, organic light emitting devices are being spotlighted in the field of display technology. Such an organic light emitting device is a device emitting light which is generated when electrons and holes are coupled together, and then diminishes.

The organic light emitting device basically includes an electrode for injecting holes, an electrode for injecting electrons, and a light emitting layer, and has a structure where the light emitting layer is stacked between an anode, i.e. the electrode for injecting the holes and a cathode, i.e. the electrode for injecting the electrons. In more detail, after electrons are injected in a cathode of the organic light emitting device and holes are injected in an anode of the organic light emitting device, the electrons and holes are moved in opposite directions by an external electric field and are coupled together in a light emitting layer, then diminish while emitting light. The light emitting layer of the organic light emitting device may be formed of an organic monomer or an organic polymer.

### SUMMARY OF THE INVENTION

An aspect of the present invention provides an organic light emitting device by which leakage emission light due to a leakage current may be prevented when a light emitting material of a high efficiency is used.

Another aspect of the present invention provides an organic light emitting device by which leakage emission light due to a leakage current may be prevented, making it possible to realize a high resolution.

In accordance with an embodiment of the present invention, an organic light emitting device may include a base part; first electrodes patterned and formed on the base part; pixel defining layers formed between the patterned first electrodes to define the first electrodes in units of pixels; conductive material layers formed on the pixel defining layers; light emitting layers formed on the first electrodes; and a second electrode formed on the light emitting layers. The conductive material layers may be electrically connected to a terminal having a voltage lower than that of the first electrodes. The first electrodes are electrically connected to a first voltage. And the conductive material layers are electrically connected to a terminal having a second voltage lower than the first volt ge.

Here, the light emitting layers may be formed of a monomer or polymer organic material.

In accordance with an example, the organic light emitting device may further include at least one first auxiliary light emitting layer formed between the light emitting layers and the first electrodes. The first auxiliary light emitting layer may include at least one of a hole injection layer and a hole transport layer.

In accordance with another example, the organic light emitting device may further include a second auxiliary light emitting layer formed between the light emitting layers and the second electrode. Here, the second auxiliary light emitting layer may include at least one of an electron injection layer and an electron transport layer.

In accordance with another example, the first electrodes may be pixel electrodes. The second electrode may be a common electrode. In this case, the second electrode is formed on both the light emitting layers and the pixel defining layers and the conductive material layers.

In accordance with another example, the first electrodes may be anodes and the second electrode may be a cathode, and the terminal having a voltage lower than that of the first electrodes may be the second electrode. That is, the second electrode may be an anode and the conductive material layers may be electrically connected to the anode.

In accordance with another example, the organic light emitting device may include a ground terminal, and the terminal with a voltage lower than that of the first electrodes may be the ground terminal. In this case, the conductive material layers may be electrically connected to the ground terminal.

In accordance with another example, the conductive material layers may include metal layers. The metal layers may include at least one of molybdenum (Mo) layers, silver (Ag) layers, copper (Cu) layers, chrome (Cr) layers, and aluminum (Al) layers.

In accordance with another example, the conductive material layers may further include transparent conductive oxide (TCO) layers formed on the metal layers. Here, the transparent conductive oxide (TCO) layer may include at least one of an ITO layer, an IZO layer, and an AZO layer.

In accordance with another example, the conductive material layers may be formed in any one of forms of a mesh, lines, and combs.

In accordance with another example, the light emitting layers may include a red light emitting layer, a green light emitting layer, and a blue light emitting layer, and the conductive material layers may be formed on the pixel defining layers surrounding the green light emitting layers.

In accordance with another example, the base part may include a substrate, a TFT layer, and a flat insulating layer. The base part may be a substrate itself.

The present invention also provides a method of manufacturing the organic light emitting device.

In accordance with an exemplary embodiment, a method of manufacturing an organic light emitting device, may include the steps of: preparing a base part; forming patterns of first electrodes on the base part; forming pixel defining layers between the patterned first electrodes such that the first electrodes are defined in units of pixels; forming conductive material layers on the pixel defining layers; forming light emitting layers on the first electrodes defined in units of pixels; and forming a second electrode on the light emitting layers. The conductive material layers may be electrically connected to a terminal having a voltage lower than that of the first electrodes. The first electrodes are electrically connected to a first voltage. And the conductive material layers are electrically connected to a terminal having a second voltage lower than the first voltage.

In accordance with another example, the method may further include the step of forming at least one first auxiliary light emitting layer after the step of forming the conductive material layers and before the step of forming the light emitting layers. The step of forming the first auxiliary light emitting layer may include at least one of the steps of: forming a hole injection layer; and forming a hole transport layer.

In accordance with another example, the method may further include the step of forming at least one second auxiliary light emitting layer after the step of forming the light emitting layers and before the step of forming the second electrode. The step of forming the second auxiliary light emitting layer may include at least one of the steps of: forming an electron transport layer; and forming an electron injection layer.

In accordance with another example, the step of forming the conductive material layers may include the step of forming metal layers. Here, the metal layers may be formed of at least one of molybdenum (Mo) layers, silver (Ag) layers, copper (Cu) layers, chrome (Cr) layers, and aluminum (Al) layers.

In accordance with another example, the method may further include the step of forming a transparent conductive oxide (TCO) layer before or after the step of forming metal layers in the step of forming the conductive material layers. The transparent conductive oxide (TCO) layer may include at least one of an ITO layer, an IZO layer, and an AZO layer.

In accordance with another example, the conductive material layers may be formed in any one of forms of a mesh, lines, and combs.

In accordance with another example, the step of forming the light emitting layers may include the steps of forming a red light emitting layer, forming a green light emitting layer, and forming a blue light emitting layer, the conductive material layers being formed in a form of traps surrounding the green light emitting layer.

In accordance with another example, the first electrode may be an anode and the second electrode may be a cathode, and the step of forming the second electrode may include the step of electrically connecting the conductive material layer to the second electrode.

The organic light emitting device may include a ground terminal and the terminal having a voltage lower than that of the first electrode is the ground terminal, and the method may further include the step of electrically connecting the conductive material layers to the ground terminal during or after the step of forming the conductive material layers.

In accordance with another embodiment of the present invention, a organic light emitting device may include a base part; first electrode patterns formed on the base part; pixel defining layers formed between the first electrode patterns to define the first electrode patterns in units of pixels; conductive material layers formed on the pixel defining layers; at least one first auxiliary light emitting layer formed on the first electrode patterns, the pixel defining layers, and the conductive material layers; light emitting layers formed on the first auxiliary light emitting layer; at least one second auxiliary light emitting layer formed on the light emitting layers; and a second electrode formed on the second auxiliary light emitting layer. The conductive material layer may be electrically connected to a terminal having a voltage lower than that of the first electrode and the light emitting layers may be formed on the upper part of the first electrode patterns defined in units of pixels. The first electrode patterns are electrically connected to a first voltage. And the conductive material layers are electrically connected to a terminal having a second voltage lower than the first voltage.

In accordance with another embodiment of the present invention, a method of manufacturing an organic light emitting device, may include the steps of: preparing a base part; forming first electrode patterns on the base part; forming pixel defining layers between the first electrode patterns such that the first electrode patterns are defined in units of pixels; forming conductive material layers on the pixel defining layers; forming at least one first auxiliary light emitting layer on the first electrode patterns, the pixel defining layers, and the conductive material layers; forming light emitting layers on the first auxiliary light emitting layer; forming at least one second auxiliary light emitting layer on the light emitting layers; and forming a second electrode on the second auxiliary light emitting layer. The conductive material layer may be electrically connected to a terminal having a voltage lower than that of the first electrode, and the light emitting layers may be formed on upper part of the first electrode patterns defined in units of pixels. The first electrode patterns are electrically connected to a first voltage. And the conductive material layers are electrically connected to a terminal having a second voltage lower than the first voltage.

In accordance with an organic light emitting device of the present invention, a leakage current generated between pixels when a current flows from one pixel to an adjacent pixel of a light emitting part may be prevented, making it possible to prevent undesired emission of light in the adjacent pixel. As a result, colors may be excellently realized, and light emitting quality may be improved.

In accordance with the present invention, leakage emission light due to a leakage current may be restrained in an organic light emitting device of a high resolution which uses a light emitting material of a high efficiency. Accordingly, an organic light emitting device may improve color realization and light emitting quality while satisfying a recent demand on a product of low power consumption and high resolution.

### BRIEF DESCRIPTION OF THE DRAWINGS

A more complete appreciation of the invention, and many of the attendant advantages thereof, will be readily apparent as the same becomes better understood by reference to the following detailed description when considered in conjunction with the accompanying drawings in which like reference symbols indicate the same or similar components, wherein:

FIG. 1 is a cross-sectional view schematically illustrating an example of a general structure of an organic light emitting device;

FIG. 2 is a cross-sectional view schematically illustrating another example of a structure of an organic light emitting device;

FIG. 3 is a plane view diagrammatically illustrating the light emitting layers formed on the substrate or the base part;

FIG. 4A shows leakage emission light of green pixels due to light emission of red pixels;

FIG. 4B shows leakage emission light of green pixels due to light emission of blue pixels;

FIG. 5 is a cross-sectional view diagrammatically illustrating an example of an organic light emitting device constructed with an embodiment of the present invention;

FIGS. 6A through 6D are plane views diagrammatically illustrating planar dispositions of the conductive material layers in the organic light emitting device constructed with an embodiment of the present invention;

FIG. 7A is a circuit diagram illustrating a flow of a leakage current in a contemporary organic light emitting device;

FIG. 7B is a circuit diagram illustrating a flow of a leakage current in the organic light emitting device constructed with an embodiment of the present invention, wherein a current is not leaked to an adjacent pixel;

FIGS. 8A through 8I diagrammatically illustrate an example of a process of manufacturing an organic light emitting device constructed with an embodiment of the present invention;

FIGS. 9A and 9B show a state where leakage emission light is not generated by preventing a leakage current from being generated in the organic light emitting device constructed with an embodiment of the present invention; and

FIG. 10 is a flow chart showing an example of a process of manufacturing an organic light emitting device constructed with an embodiment of the present invention.

### DETAILED DESCRIPTION OF THE PREFERRED EMBODIMENTS

Hereinafter, an exemplary embodiment of the present invention will be described in more detail with reference to the accompanying drawings. However, the scope of the present invention is not limited to the below-described embodiment and the drawings.

For reference, the elements and their shapes are simply drawn or exaggerated in the drawings to help understanding of the present invention. In the drawings, the same reference numerals denote the same elements.

Further, when it is described that a layer or element is located on another layer or element, the layer or element may not only directly contact the other layer or element, but also a third layer or element may be interposed therebetween.

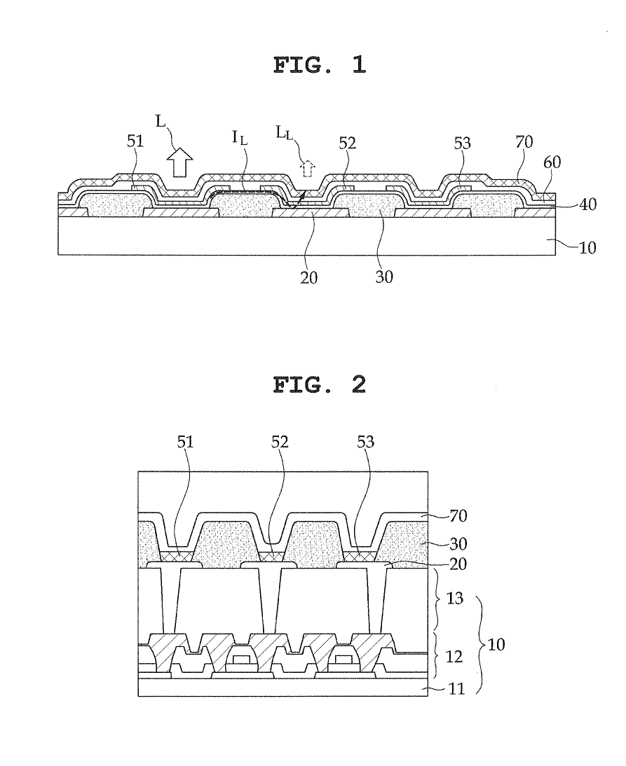

FIG. 1 schematically illustrates a general structure of an organic light emitting device.

In reference to FIG. 1, anodes 20 as first electrodes are formed on a base part 10 for the organic light emitting device, and the anodes 20 are divided and physically separated by pixel defining layers (PDLs) 30 in units of pixels. A hole injection layer 40 is formed on the anodes 20 and the pixel defining layers 30, and light emitting layers are formed on the hole injection layer 40. In this structure, the light emitting layers are classified into a red light emitting layer 51, a green light emitting layer 52, and a blue light emitting layer 53. An electron transport layer 60 is formed on the light emitting layers 51, 52, and 53, and a cathode 70 as a common electrode is formed on the electron transport layer 60. In one embodiment, the cathode 70 may be formed to cover the entirety of the electron transport layer 60 and the light emitting layers disposed under the cathode 70.

A hole transport layer (not shown) may be further formed between the light emitting layers 51, 52, and 53 and the hole injection layer 40, and the hole transport layer may replace the hole injection layer 40. An electron injection layer may be further disposed between the electron transport layer 60 and the cathode 70, and the electron injection layer (not shown) may replace the electron transport layer 60.

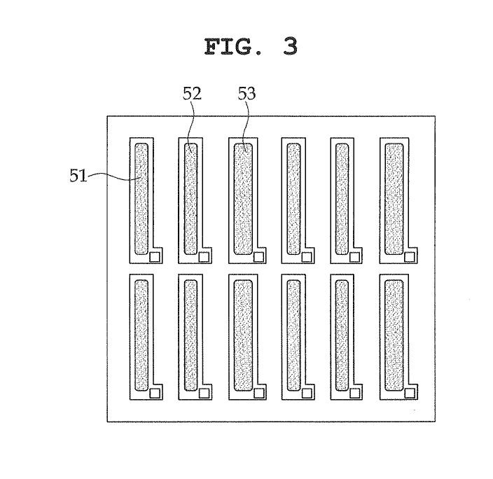

FIG. 2 schematically illustrates an organic light emitting device including the anode 20, the light emitting layers 51, 52, and 53, the cathode 70, the pixel defining layers 30, and the base part 10. Here, the base part 10 includes a substrate 11, a TFT layer 12 formed on the substrate 11, and a flat insulation layer 13 formed on the TFT layer 12. Occasionally, the stack body including the substrate 11, the TFT layer 12, and the flat insulation layer 13 is referred to as a substrate.

FIG. 3 is a plane view illustrating light emitting layers formed on the substrate or the base part 10. Here, the light emitting layers may be classified into a red light emitting layer 51, a green light emitting layer 52, and a blue light emitting layer 53. The individually defined light emitting layers form independent pixels respectively.

Since the resolutions of the display devices are recently getting higher, the resolutions of the pixels (ppi) also increase, and the intervals between the pixels are gradually becoming narrower. Further, in recent years, as the efficiencies of light emitting materials forming the organic light emitting devices are increasing, a higher brightness may be achieved with a lower current and a lower voltage, and thus the power consumption of the display devices may be reduced.

However, since the intervals between the pixels are gradually becoming narrower due to higher resolutions of the pixels and light may be emitted by a small amount of currents due to a high efficiency of a light emitting material forming an organic light emitting device, light may be emitted by a very small amount of currents leaked from one pixel to another adjacent pixel. As a result, an adjacent pixel which is not intended to emit light often emits light. The light emitted due to leakage currents is also referred to leakage emission light. If the leakage emission is generated, a color mixture is generated and a color coordinate is changed. In addition, when the leakage emission due to a leakage current is generated in a low-brightness region, black brightness may increase.

In particular, for example, a green material has a high efficiency, so when a red pixel or a blue pixel adjacent to a green pixel is driven, even the adjacent green pixel emits light.

Turning back to FIG. 1. FIG. 1 illustrates that, when currents are supplied to a red light emitting layer 51 to drive the red light emitting layer 51, most of the supplied currents cause the red light emitting layer 51 to emit light L. Some of the currents are however leaked from the red light emitting layer 51 towards the green light emitting layer 52. The leakage currents I_{L} leaked towards the green light emitting layer 52 may cause the green light emitting layer 52 to emit light to produce leakage emission light L_{L}.

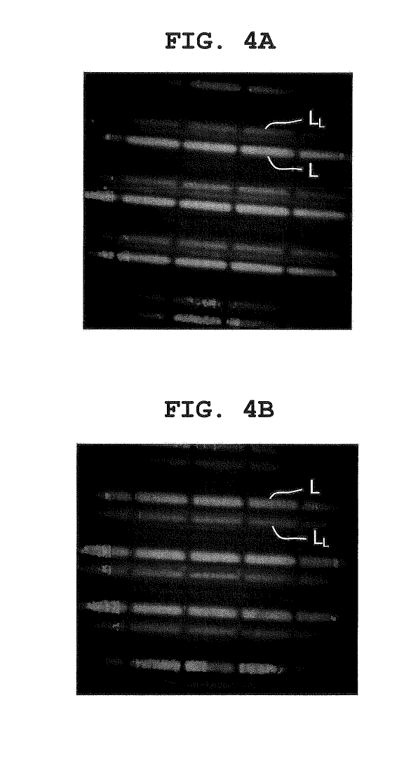

The leakage emission light of the green light emitting layer (green pixel) due to emission of light of the red light emitting layer (red pixel) may be observed from FIG. 4A. FIG. 4B shows a leakage emission light of the green light emitting layer (green pixel) due to emission of light of the blue light emitting layer (blue pixel).

The leakage emission light is one of the phenomena generated as an efficiency of a light emitting material and a resolution of a display device increase.

Accordingly, a method of lowering an efficiency of a light emitting material or lowering a resolution of a display device may be used to restrain a leakage emission light. However, such method is not preferable to solve the problem of the leakage emission light due to the leakage currents by the method of lowering the efficiency of a light emitting material or lowering the resolution of a display device, considering that a demand on low-power and high-resolution products is recently increasing.

Therefore, an alternative technology for restraining a leakage emission light due to leakage currents without lowering a resolution of a display unit using a high-efficiency light emitting material is urgently required.

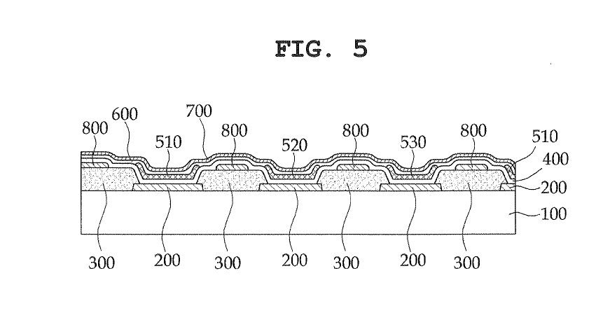

FIG. 5 is a cross-sectional view diagrammatically illustrating an organic light emitting device constructed with an embodiment of the present invention. Since the organic light emitting device is used for a display unit or a panel of a display unit, it is also referred to as “an organic light emitting display device”. Among the terms, the term “an organic display device” will be used in the description of the present invention.

The organic light emitting device of FIG. 5 includes a base part 100, first electrodes 200 patterned on the base part 100, pixel defining layers 300 formed between the patterned first electrodes 200, conductive material layers 800 formed on the pixel defining layers 300, light emitting layers 510, 520, and 530 formed on the first electrodes 200, and a second electrode 700 formed on the light emitting layers 510, 520, and 530. The organic light emitting device illustrated in FIG. 5 includes a first auxiliary light emitting layer 400 formed between the light emitting layers 510, 520, and 530 and the first electrodes 200 and a second auxiliary light emitting layer 600 formed between the light emitting layers 510, 520, and 530 and the second electrode 700.

Here, the light emitting layers, the first auxiliary light emitting layer 400, and the second auxiliary light emitting layer 600 correspond to organic layers.

As shown in FIG. 5, the first electrodes 200 may be defined in units of pixels by the pixel defining layers 300, the light emitting layers 510, 520, and 530 are formed on the first electrodes 200 defined in units of pixels by the pixel defining layers 300. Here, the first electrodes 200 correspond to pixel electrodes.

The light emitting layers 510, 520, and 530 include the red light emitting layer 510, the green light emitting layer 520, and the blue light emitting layer 530. When the light emitting layers 510, 520, and 530 are formed of a red light emitting material, a green light emitting material, and a blue light emitting material respectively, the light emitting materials are organic materials. The light emitting materials may be selected from those used in the art to which the present invention pertains.

It can be seen from FIG. 5 that the first auxiliary light emitting layer 400 is formed on an entire upper surface of the patterned first electrodes 200, the conductive material layers 800, and the pixel defining layers 300.

The first auxiliary light emitting layer 400 may be a hole injection layer or a hole transport layer. Alternatively, the first auxiliary light emitting layer 400 may include two layers, and may include both a hole injection layer and a hole transport layer separately.

It is illustrated in the embodiment of FIG. 5 that the first auxiliary light emitting layer 400 is a hole injecting and transporting layer having both a hole injection function and a hole transport function.

It can be seen from FIG. 5 that the second auxiliary light emitting layer 600 is formed on an entire upper surface of the light emitting layer 510, 520, 530, and first auxiliary light emitting layer 400. The second auxiliary light emitting layer 600 may be an electron injection layer or an electron transport layer. Alternatively, the second auxiliary light emitting layer 600 may include two layers, and may include both an electron injection layer and an electron transport layer separately.

It is illustrated in the embodiment of FIG. 5 that the second auxiliary light emitting layer 600 is an electron transport layer.

In the embodiment of FIG. 5, the first electrodes 200 are anodes acting as pixel electrodes and the second electrode 700 is a cathode acting as a common electrode.

The first electrodes 200 acting as anodes are formed on the base part 100 in a patterned form. The first electrodes 200 acting as pixel electrodes supply electric charges to the red light emitting layer 510, the green light emitting layer 520, and the blue light emitting layer 530. The red light emitting layer 510, the green light emitting layer 520, and the blue light emitting layer 530 formed on the first electrodes 200 become a red pixel, a green pixel, and a blue pixel respectively.

The second electrode 700, i.e. the cathode, is formed on an entire upper surface of the second auxiliary light emitting layer 600.

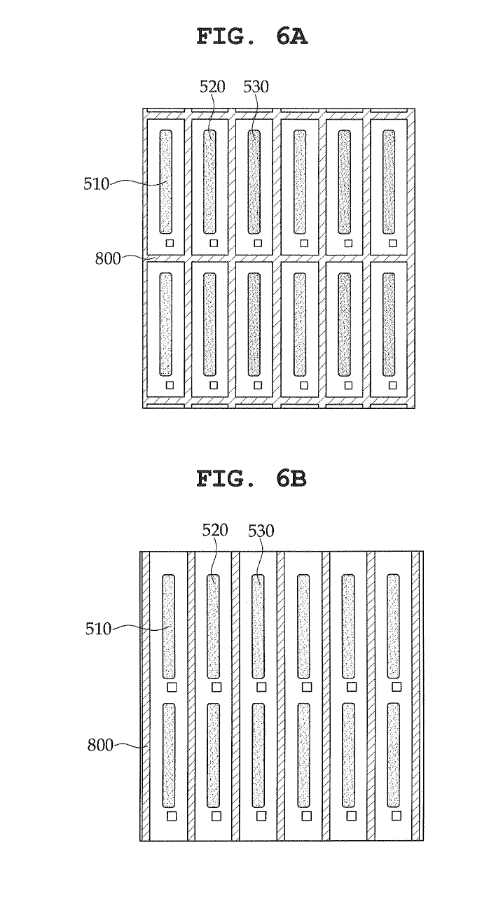

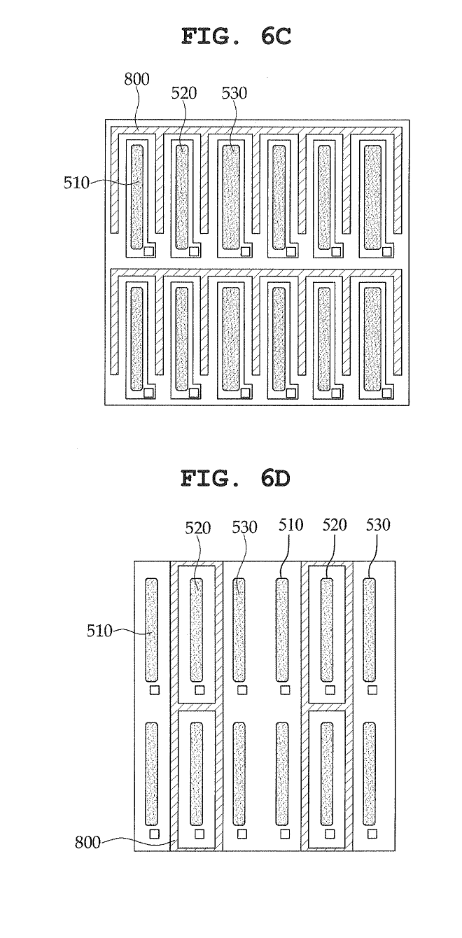

FIGS. 6A through 6D are plane views showing exemplary planar dispositions of conductive material layers 800 in the organic light emitting device constructed with an embodiment of the present invention.

As illustrated in FIG. 6A, the conductive material layers 800 may be formed in a form of a mesh between the light emitting layers 510, 520, and 530. The conductive material layers 800 may be formed in a mesh disposed between two neighboring light emitting layers.

As illustrated in FIG. 6B, they may be formed in a form of lines. The conductive material layers 800 may be formed in lines disposed between the red light emitting layers 510, the green light emitting layers 520, and the blue light emitting layers 530.

As illustrated in FIG. 6C, they may be formed in a form of combs.

As illustrated in FIG. 6D, the conductive material layers 800 may be formed in a form of traps surrounding one or more of specific light emitting layers. As an example, an efficiency of a green light emitting material is excellent, so leakage emission light is mainly generated in the green light emitting layer. Accordingly, the conductive material layers 800 may be formed in a form of traps surrounding the green light emitting layer 520.

Turning now back to FIG. 5. As illustrated in FIG. 5, the conductive material layers 800 are formed on the pixel defining layers 300, and are electrically insulated from the first electrodes 200.

The pixel defining layers 300 may be formed of an electrical insulating material. The material of the pixel defiling layers 300 may be selected from those used in the art to which the present invention pertains. The pixel defining layers are also referred to as “separation walls” or “pixel definition lines”. They are also briefly referred to “PDLs”. Among them, the term “pixel defining layers” will be used in the description of the invention.

The pixel defining layers 300 are generally formed between the first electrodes 200 to define the first electrodes 200 in units of pixels.

The first auxiliary light emitting layer 400 is disposed on the conductive material layer 800, and the first auxiliary light emitting layer 400 is formed on entire upper surfaces of the first electrodes 200, the conductive material layers 800, and the pixel defining layers 300.

As the conductive material layers 800 are formed in the above-described way, the leakage currents I_{L} generated in one light emitting layer 510 do not flow into an adjacent light emitting layer 520 but gather in the conductive material layers 800. Therefore, the leakage currents I_{L} are prevented from flowing into the adjacent light emitting layer 520.

Meanwhile, the conductive material layers 800 may be electrically connected to a terminal having a voltage lower than that of the first electrodes 200. As an example, the conductive material layers 800 may be electrically connected to the second electrode 700, i.e. the cathode.

The conductive material layers 800 may be connected to a terminal formed in the organic light emitting device separately. That is, the organic light emitting device may include a ground terminal, and the ground terminal may become the terminal having a voltage lower than that of the first electrode. As a result, the conductive material layers 800 may be connected to the ground terminal.

As the conductive material layers 800 are connected to the cathode or to the ground terminal, the leakage currents I_{L} having gathered in the conductive material layers 800 may be easily discharged.

As a result, leakage emission light may be prevented from being generated in the light emitting layer 520 adjacent to the light emitting layer 510 where the leakage currents I_{L} are generated.

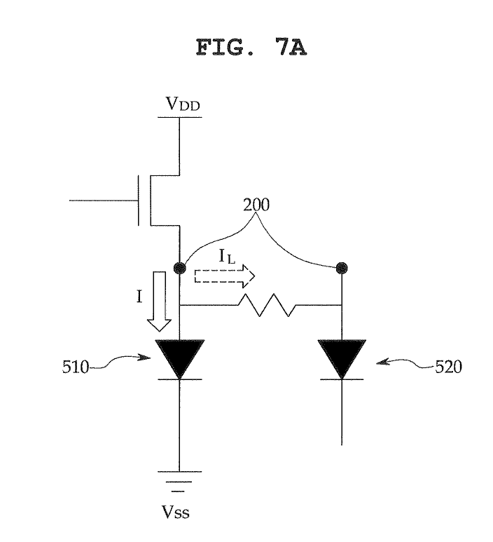

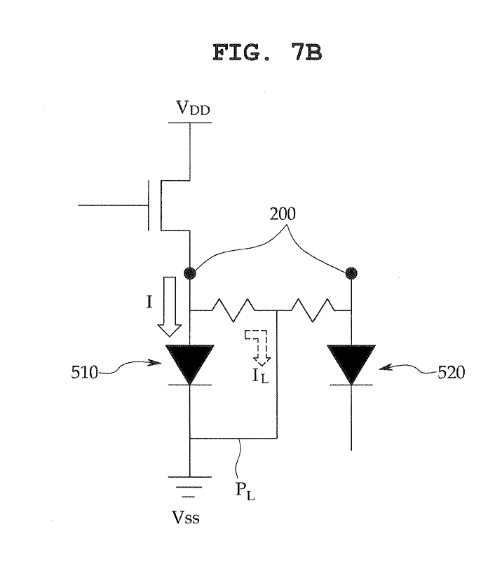

In this regard, FIG. 7A illustrates a flow of a leakage current in a contemporary organic light emitting device, and FIG. 7B illustrates a flow of a leakage current in the organic light emitting device constructed with an embodiment of the present invention.

It may be seen from FIG. 7A that, in a contemporary organic light emitting device, the leakage currents I_{L} generated in the red light emitting layer 510 flow into the adjacent green light emitting layer 520. Even when the leakage currents I_{L} correspond to a small amount, they may cause the green light emitting layer 520 to emit light. As a result, the leakage emission light as shown in FIG. 4A may be generated.

On the other hand, it may be seen from FIG. 7B that, in the organic light emitting device constructed with an embodiment of the present invention, the leakage currents I_{L} generated in the red light emitting layer 510 flow through a path P_{L} (leakage path) formed by the conductive material layer 800 instead of flowing into the green light emitting layer 520 adjacent to the red light emitting layer 510.

When the conductive material layer 800 is electrically connected to the cathode 700, the leakage currents will flow to the cathode, and when the conductive material layer 800 is connected to a separate ground line, the leakage currents will flow to the ground line. As a result, leakage emission light is prevented from being generated in the light emitting layer 520 adjacent to the light emitting layer 510 where the leakage currents are generated.

The conductive material layers 800 are electrically conductive layers. The conductive material layers 800 are formed on the pixel defining layers 300, and are generally formed after the formation of the first electrodes 200. Therefore, a material which minimizes the damage, in particular, to the first electrodes 200 in the process of forming the conductive material layers 800, may be used.

The conductive material layers 800 may be a single layer or a plurality of stacked layers. In accordance with an example of the present invention, the conductive material layers 800 may include metal layers.

The conductive material layers 800 are patterned on the pixel defining layers 300, and a method of patterning the conductive material layers 800 including the metal layers includes photoresist (PR) and etching processes. An etching solution used in the etching process may damage the first electrode 200. Thus, when the process of forming the conductive material layer includes the etching process, the conductive material layers may be formed of such a metal which minimizes the damage to the first electrodes 200 in the etching process.

In the embodiment, the first electrodes 200 include transparent conductive oxide (TCO) layers. The transparent conductive oxide (TCO) layer may be selected from those generally used in the art to which the present invention pertains, and for example, may include an ITO layer, an IZO layer, and an AZO layer. In the present embodiment, ITO is used to form first electrodes 200.

Then, in order to minimize damage to the first electrodes 200, the first electrodes 200 consisting of ITO may be hardened before the formation of the conductive material layers 800.

The conductive material layers 800 may be formed of, for example, molybdenum (Mo), chrome (Cr), or aluminum (Al). During the processes of patterning molybdenum (Mo), chrome (Cr), or aluminum (Al), an etching process may be performed. In the etching process, an etching solution containing nitric acid, phosphoric acid, or acetic acid is used, but the etching solution used above may not severely corrode the hardened ITO electrode.

Considering these aspects, the conductive material layers 800 may be formed of any one of molybdenum (Mo), silver (Ag), copper (Cu), chrome (Cr), and aluminum (Al). That is, the conductive material layers 800 may include at least one of molybdenum (Mo) layers, silver (Ag) layers, copper (Cu) layers, chrome (Cr) layers, and aluminum (Al) layers. The conductive material layers 800 may include layers formed of a metal other than the above mentioned metal layers, and may have a structure where two or more layers are stacked.

The conductive material layers 800 may further include transparent conductive oxide (TCO) layers formed on the metal layers. Here, as the transparent conductive oxide (TCO) layers, those layers generally used in the art to which the present invention pertains may be used. For example, the transparent conductive oxide (TCO) layers may include at least one selected from ITO layers, IZO layer, and AZO layers.

As an example of the present invention, the base part 100 may include a substrate, a TFT layer, and a flat insulation layer. The base part 100 may be only a substrate. Accordingly, the base part 100 may occasionally have the same meaning as a substrate.

For simplicity, FIG. 5 does not illustrate the individual elements of the base part 100.

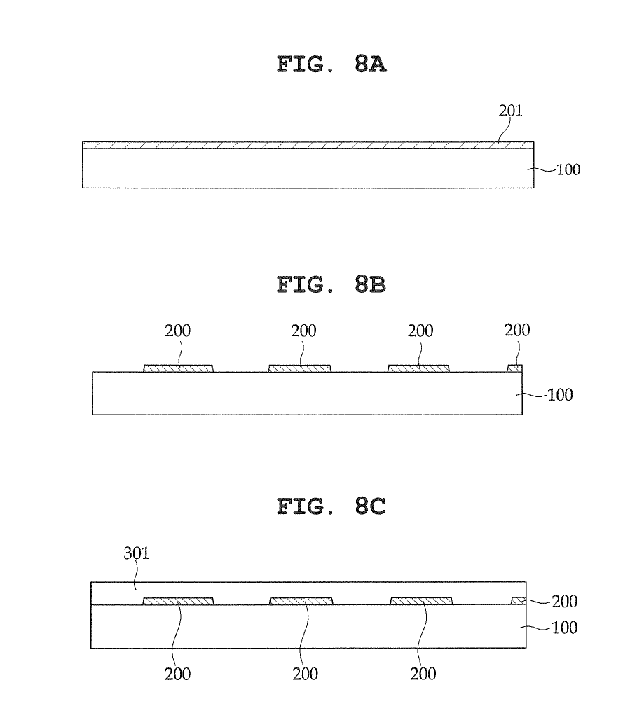

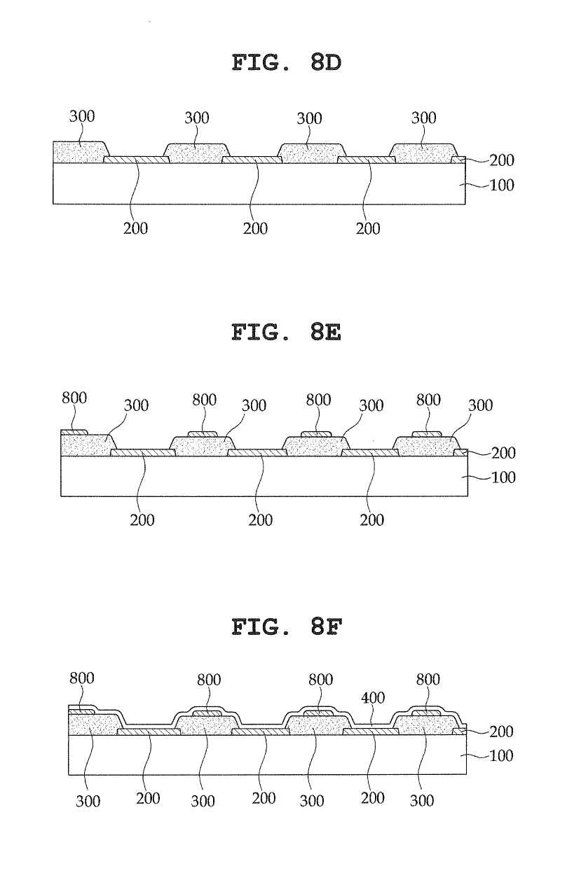

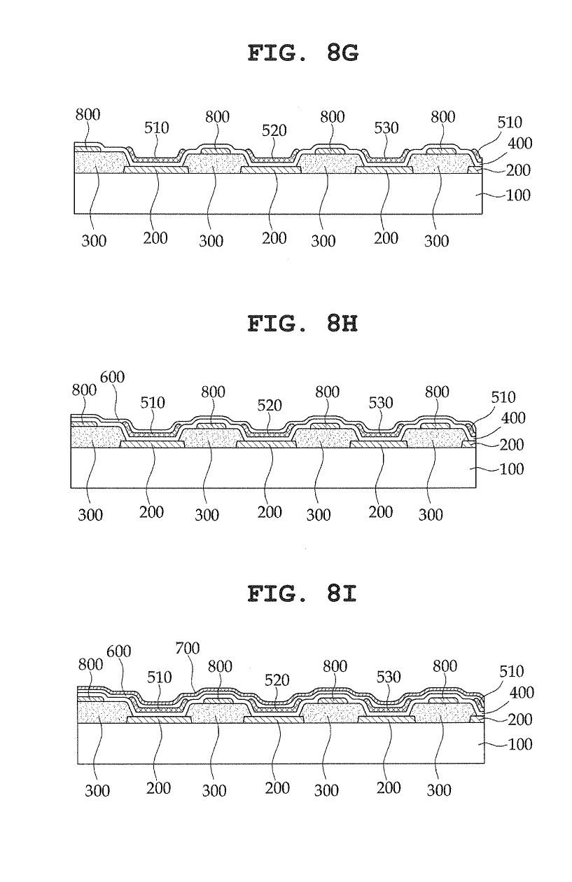

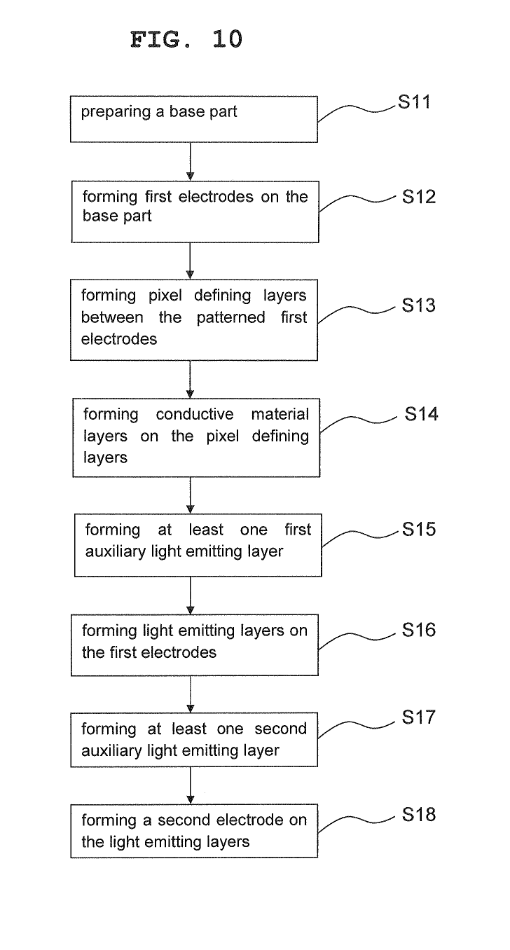

FIGS. 8A to 8H diagrammatically illustrate a process of manufacturing an organic light emitting device constructed with an embodiment of the present invention, and FIG. 10 is a flow chart showing an example of a process of manufacturing an organic light emitting device constructed with an embodiment of the present invention. Hereinafter, a method of manufacturing an organic light emitting device according to the present invention will be described with reference to FIGS. 8A to 8H, and FIG. 10.

A base part 100 is prepared first, and a material 201 for forming first electrodes are applied to the base part 100 (FIG. 8A, S11 of FIG. 10).

The process of preparing the base part 100 may include a step of preparing a substrate, a step of forming a TFT layer, and a step of forming a flat insulation layer. In the present embodiment, a description of the process will be entirely omitted. Meanwhile, the base part may be only a substrate.

A method generally used in the art to which the present invention pertains may be applied as a method of applying a material 201 for forming the first electrodes. It is apparent that an example of such a method includes sputtering and a method other than sputtering may be applied.

The first electrodes 200 may include at least one of a transparent conductive oxide (TCO) layer and a metal layer. Accordingly, the process of applying the material 201 for forming the first electrodes 200 may include at least one of a step of forming a transparent conductive oxide (TCO) layer and forming a metal layer. Here, the transparent conductive oxide (TCO) layer may include at least one of an ITO layer, an IZO layer, and an AZO layer. The metal layer may include at least one of a silver (Ag) layer, a copper (Cu) layer, and an aluminum layer (Al).

Meanwhile, the first electrodes 200 may have a structure where an ITO layer, a silver (Ag) layer, and an ITO layer are sequentially stacked, respectively. In order to form the first electrodes 200 where an ITO layer, a silver (Ag) layer, and an ITO layer are sequentially stacked, a step of forming an ITO layer, a step of forming a silver (Ag) layer, and a step of forming an ITO layer may be sequentially performed.

In the present embodiment, a case of the first electrodes including the ITO layers will be described as an example.

The first electrodes 200 are formed by patterning the material 201 which is applied on the base part 100 (FIG. 8B, S12 of FIG. 10). A method generally used in the art to which the present invention pertains may be applied to the patterning method.

As shown in FIG. 8C, a pixel defining layer forming material 301 is applied on the patterned first electrodes 200 and base part 100. The pixel defining layer forming material 301 may be an electrically insulating material, and a material generally used in the art to which the present invention pertains may be used as the material 301.

The pixel defining layers 300 are formed by patterning the pixel defining layer forming material 301 (FIG. 8D, S13 of FIG. 10).

A method generally used in the art to which the present invention pertains may also be applied to the method for patterning pixel defining layers.

As illustrated in FIG. 8D, the pixel defining layers 300 are formed between the first electrodes 200 such that upper portions of the first electrodes 200 are exposed.

The conductive material layers 800 are formed on the pixel defining layers 300 (FIG. 8E, S14 of FIG. 10).

The conductive material layers 800 are electrically conductive.

The conductive material layers 800 may be a single layer or a plurality of stacked layers.

The conductive material layers 800 may be formed by applying a single layer or a plurality of layers of the conductive material layer forming material on the pixel defining layers and patterning it. The conductive material layers 800 may also be formed by applying a single layer or a plurality of layers of the conductive material layer forming material on entire upper surfaces of the pixel defining layers and the first electrodes and patterning it.

The first electrodes 200 and the pixel defining layers 300 may be damaged in the process of forming the conductive material layers 800, and in particular, the first electrodes 200 and the pixel defining layers 300 may be damaged in the process of patterning the conductive material layers 800.

In more detail, an example of patterning the conductive material layers 800 on the pixel defining layers 300 includes photoresist (PR) and etching processes. An etching solution is used in the etching process and may damage the first electrode 200 and the pixel defining layers 300. Therefore, when the process of forming the conductive material layer includes the etching process, the conductive material layers may be formed of such a metal which minimizes damage to the first electrodes 200 in the etching process.

In particular, damages of the first electrode may directly influence a light emitting efficiency of the device. Accordingly, the material for forming the conductive material layers 800 may be selected from those which minimizes damage to the first electrodes 200.

Since the conductive material layers 800 is electrically conductive, the conductive material layers according to the present invention include metal layers. In order to minimize damage to the first electrodes 200 in the process of patterning the conductive material layers 800 which include metal layers, the first electrodes 200 may be hardened before the conductive material layers 800 are formed.

In the present embodiment, it will be illustrated as an example that ITO among the transparent conductive oxides may be used for the first electrode. Accordingly, the embodiment may further include a step of hardening the first electrodes consisting of ITO before a step of forming the conductive material layers 800.

In more detail, the conductive material layers 800 may be formed of, for example, molybdenum (Mo), chrome (Cr), or aluminum (Al). During the processes of patterning molybdenum (Mo), chrome (Cr), or aluminum (Al), an etching process is performed, and an etching solution used in the etching process, which contains nitric acid, phosphoric acid, or acetic acid, does not severely corrode the hardened ITO electrode.

The conductive material layers 800 may include layers formed of a metal other than the above mentioned metal layers, and may have a structure where two or more layers are stacked.

The conductive material layers 800 may further include transparent conductive oxide (TCO) layers formed on the metal layers. Here, those layers generally used in the art to which the present invention pertains may be used for the transparent conductive oxide (TCO) layers. For example, the transparent conductive oxide (TCO) layers may include at least one selected from ITO layers, IZO layer, and AZO layers.

In the present embodiment, it will be described as an example that the conductive material layers 800 are formed of molybdenum (Mo). Corrosion of the hardened ITO electrode may be minimized by adjusting composition of the etching solution used in the etching process for molybdenum (Mo).

When the conductive material layers 800 are patterned, they may be formed in any one of forms of a mesh, lines, and combs between the light emitting layers 510, 520, and 530. When the conductive material layers are patterned, the conductive material layers 800 may have a form of a trap surrounding the green light emitting layer on the pixel defining layers surrounding the green light emitting layers.

A first auxiliary light emitting layer 400 is formed before the light emitting layers 510, 520, and 530 are formed in the process of the present embodiment (FIG. 8F, S15 of FIG. 10).

Referring to FIG. 8F, it may be seen that the first auxiliary light emitting layer 400 is formed on entire upper surfaces of the first electrodes 200, the conductive material layers 800, and the pixel defining layers 300.

The first auxiliary light emitting layer 400 may be any one of a hole injection layer and a hole transport layer, and may include both a hole injection layer and a hole transport layer.

It is illustrated in FIG. 8F that the first auxiliary light emitting layer 400 is a hole injecting and transporting layer having both a hole injection function and a hole transport function.

For reference, the step of forming the first auxiliary light emitting layer may include any one of a step of forming a hole injection layer and a hole transport layer, or may include both the steps.

For example, when the first light emitting layer 400 includes two layers, the hole transport layer may be formed after the hole injection layer is formed.

Next, the light emitting layers 510, 520, and 530 are formed on the first auxiliary light emitting layer 400 (FIG. 8G, S16 of FIG. 10).

The light emitting layers 510, 520, and 530 are located on the first electrodes 200 defined in units of pixels by the pixel defining layers 300. The light emitting layers 510, 520, and 530 include the red light emitting layer 510, the green light emitting layer 520, and the blue light emitting layer 530. Since the light emitting layers 510, 520, and 530 may be formed by a general method used in the art to which the present invention pertains, a detailed description of the method of forming the light emitting layers will be omitted.

Meanwhile, in the process of the present embodiment, a second auxiliary light emitting layer 600 is formed after the light emitting layers 510, 520, and 530 are formed and before the second electrode 700 is formed (FIG. 8H, S17 of FIG. 10).

The second auxiliary light emitting layer 600 is formed on the light emitting layers 510, 520, and 530 and the first auxiliary light emitting layers 400.

The second auxiliary light emitting layer 600 may include any one of an electron injection layer and an electron transport layer. Accordingly, the step of forming the second auxiliary light emitting layer 600 may include at least a step of forming an electron transport layer and a step of forming an electron injection layer.

In the present embodiment, it is illustrated that the second auxiliary light emitting layer 600 is an electron transport layer. Accordingly, in FIG. 8H, an electron transport layer is formed as the second auxiliary light emitting layer 600.

Alternatively, the second auxiliary light emitting layer 600 may include two layers to include both the electron injection layer and the electron transport layer.

The second electrode 700 is formed on the second auxiliary light emitting layer 600 (FIG. 81, S18 of FIG. 10). The second electrode 700 is formed on an entire surface of the second auxiliary light emitting layer 600.

When leakage currents are generated in the process of emitting light in the organic light emitting device constructed with the present invention, the leakage currents are introduced into the conductive material layers 800. The introduced leakage currents are caused by charges generated in the first electrodes 200. In the meantime, the conductive material layers 800 need to be electrically connected to another terminal to discharge the leakage currents.

In accordance with the present invention, the conductive material layers 800 are electrically connected to a terminal having a voltage lower than that of the first electrodes.

For example, when the first electrodes 200 are anodes and the second electrode 700 is a cathode, the second electrode 700 is connected to a voltage lower than the voltage connected to the first electrodes 200. In this case, the conductive material layers 800 may be electrically connected to the second electrode 700. In order to electrically connect the conductive material layers 800 to the second electrode 700, the step of forming the second electrode 700 includes a step of electrically connecting the conductive material layer 800 to the second electrode 700. A general method used in the art to which the present invention pertains may be used as the method of electrically connecting the conductive material layer 800 to the second electrode 700. For example, the method includes a method of forming a separate connecting bridge and a method of forming a hole.

Meanwhile, the organic light emitting device generally may include a ground terminal. The ground terminal may act as a terminal having a voltage lower than that of the first electrodes 200 and the conductive material layers 800 may be connected to the ground terminal. In this case, the conductive material layers 800 may be electrically connected to the ground terminal during the step of forming the conductive material layers 800 or after the step of forming the conductive material layers 800. Occasionally, the conductive material layers 800 may be electrically connected to the ground terminal after the second electrode 700 is formed.

Although not illustrated, in the embodiment, a separate bridge may be formed to electrically connect the conductive material layers 800 to the second electrode 700 in the step of forming the second electrode 700.

The organic light emitting device may be manufactured through the above process.

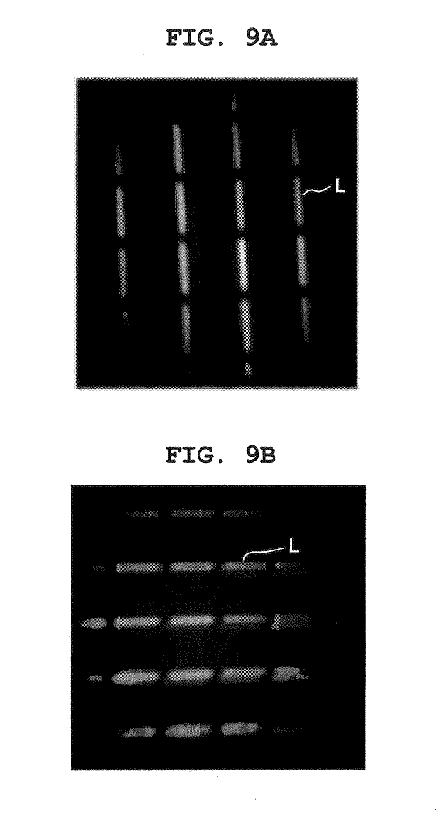

FIGS. 9A and 9B show emission of light of the organic light emitting device manufactured according to an example of the present invention. It may be seen from FIG. 9A that when red pixels are turned on, only the red pixels emit light, and it may be seen from FIG. 9B that when blue pixels are turned on, only the blue pixels emit light. In this way, the organic light emitting device constructed with an embodiment of the present invention prevents generation of leakage currents without causing leakage emission light.

In another embodiment of the present invention, there is provided an organic light emitting device including a base part; first electrode patterns formed on the base part; pixel defining layers formed between the first electrode patterns to define the first electrode patterns in units of pixels; conductive material layers formed on the pixel defining layers; at least one first auxiliary light emitting layer formed on the first electrode patterns, the pixel defining layers, and the conductive material layers; light emitting layers formed on the first auxiliary light emitting layer; at least one second auxiliary light emitting layer formed on the light emitting layers; and a second electrode formed on the second auxiliary light emitting layer. The conductive material layer is electrically connected to a terminal having a voltage lower than that of the first electrode, and the light emitting layers are formed on upper parts of the first electrode patterns defined in to units of pixels.

Then, the first auxiliary light emitting layer may include at least one of a hole injection layer and a hole transport layer, and the second auxiliary light emitting layer may include at least one of an electron injection layer and an electron transport layer.

In the example, the first electrode may be an anode and the second electrode may be a cathode, and the terminal having a voltage lower than that of the first electrode may be the second electrode. That is, the conductive material layers may be electrically connected to the second electrode, i.e. a cathode.

The organic light emitting device includes a ground terminal, and the terminal having a voltage lower than that of the first electrode is the ground terminal. That is, the conductive material layers may be electrically connected to the ground terminal.

In another example of the present invention, there is provided a method of manufacturing an organic light emitting device, the method including the steps of: preparing a base part; forming first electrode patterns on the base part; forming pixel defining layers between the first electrode patterns such that the first electrode patterns are defined in units of pixels; forming conductive material layers on the pixel defining layers; forming at least one first auxiliary light emitting layer on the first electrode patterns, the pixel defining layers, and the conductive material layers; forming light emitting layers on the first auxiliary light emitting layer; forming at least one second auxiliary light emitting layer on the light emitting layers; and forming a second electrode on the second auxiliary light emitting layer. The conductive material layer is electrically connected to a terminal having a voltage lower than that of the first electrode, and the light emitting layers are formed on upper parts of the first electrode patterns defined in units of pixels.

Here, the step of forming the first auxiliary light emitting layer may include at least one of the steps of forming a hole injection layer; and forming a hole transport layer. The step of forming the second auxiliary light emitting layer includes at least one of the steps of: forming an electron injection layer; and forming an electron transport layer.

Here, the first electrode may be an anode and the second electrode may be a cathode, and the step of forming the second electrode may include the step of electrically connecting the conductive material layers to the second electrode.

Meanwhile, the organic light emitting device may include a ground terminal and the terminal having a voltage lower than that of the first electrode may be the ground terminal, and the method may further include the step of electrically connecting the conductive material layers to the ground terminal during or after the step of forming the conductive material layers.

What is claimed is:

1. An organic light emitting device, comprising:
a base part;
first electrodes patterned and formed on the base part, the first electrodes being electrically connected to a first voltage;
pixel defining layers formed between the patterned first electrodes to define the first electrodes in units of pixels;
conductive material layers formed on the pixel defining layers, the conductive material layers being electrically connected to a terminal having a second voltage lower than the first voltage;
light emitting layers formed on the first electrodes; and
a second electrode formed on the light emitting layers.

2. The organic light emitting device as claimed in claim 1, further comprising at least one first auxiliary light emitting layer formed between the light emitting layers and the first electrodes.

3. The organic light emitting device as claimed in claim 2, wherein the first auxiliary light emitting layer includes at least one of a hole injection layer and a hole transport layer.

4. The organic light emitting device as claimed in claim 1, further comprising a second auxiliary light emitting layer formed between the light emitting layers and the second electrode.

5. The organic light emitting device as claimed in claim 4, wherein the second auxiliary light emitting layer includes at least one of an electron injection layer and an electron transport layer.

6. The organic light emitting device as claimed in claim 1, wherein the first electrodes are pixel electrodes.

7. The organic light emitting device as claimed in claim 1, wherein the first electrodes are anodes and the second electrode is a cathode, and the terminal having the second voltage is the second electrode.

8. The organic light emitting device as claimed in claim 1, wherein the organic light emitting device includes a ground terminal, and the terminal having the second voltage is the ground terminal.

9. The organic light emitting device as claimed in claim 1, wherein the conductive material layers comprise metal layers.

10. The organic light emitting device as claimed in claim 9, wherein the metal layers comprise at least one of molybdenum (Mo) layers, silver (Ag) layers, copper (Cu) layers, chrome (Cr) layers, and aluminum (Al) layers.

11. The organic light emitting device as claimed in claim 9, wherein the conductive material layers further comprise transparent conductive oxide (TCO) layers formed on the metal layers.

12. The organic light emitting device as claimed in claim 11, wherein the transparent conductive oxide (TCO) layer comprises at least one of an ITO layer, an IZO layer, and an AZO layer.

13. The organic light emitting device as claimed in claim 1, wherein the conductive material layers are formed in any one of forms of a mesh, lines, and combs.

14. The organic light emitting device as claimed in claim 1, wherein the light emitting layers include a red light emitting layer, a green light emitting layer, and a blue light emitting layer, and the conductive material layers are formed on the pixel defining layers and surround the green light emitting layers.

15. The organic light emitting device as claimed in claim 1, wherein the base part includes a substrate, a TFT layer, and a flat insulating layer.

16. The organic light emitting device as claimed in claim 1, wherein the base part is a substrate.

17. A method of manufacturing an organic light emitting device, the method comprising the steps of:
preparing a base part;
forming patterns of first electrodes on the base part and electrically connecting the first electrodes to a first voltage;
forming pixel defining layers between the patterned first electrodes such that the first electrodes are defined in units of pixels;
forming conductive material layers on the pixel defusing layers and electrically connecting the conductive material layers to a terminal having a second voltage lower than the first voltage;
forming light emitting layers on the first electrodes defined in units of pixels; and
forming a second electrode on the light emitting layers.

18. The method as claimed in claim 17, further comprising the step of forming at least one first auxiliary light emitting layer after the formation of the conductive material layers and before the formation of the light emitting layers.

19. The method as claimed in claim 18, wherein the step of forming the first auxiliary light emitting layer comprises at least one of the steps of forming a hole injection layer; and forming a hole transport layer.

20. The method as claimed in claim 17, further comprising the step of forming at least one second auxiliary light emitting layer after the formation of the light emitting layers and before the formation of the second electrode.

21. The method as claimed in claim 20, wherein the step of forming the second auxiliary light emitting layer comprises at least one of the steps of: forming an electron transport layer; and forming an electron injection layer.

22. The method as claimed in claim 17, wherein the step of forming the conductive material layers comprises the step of forming metal layers.

23. The method as claimed in claim 22, wherein the metal layers may be formed of at least one of molybdenum (Mo) layers, silver (Ag) layers, copper (Cu) layers, chrome (Cr) layers, and aluminum (Al) layers.

24. The method as claimed in claim 22, further comprising the step of forming a transparent conductive oxide (TCO) layer before or after the formation of the metal layers.

25. The method as claimed in claim 24, wherein the transparent conductive oxide (TCO) layer may be formed of at least one of an ITO layer, an IZO layer, and an AZO layer.

26. The method as claimed in claim 17, wherein the conductive material layers are formed in any one of forms of a mesh, lines, and combs.

27. The method as claimed in claim 19, wherein the step of forming the light emitting layers comprises the steps of forming a red light emitting layer, forming a green light emitting layer, and forming a blue light emitting layer, the conductive material layers being formed in a form of traps surrounding the green light emitting layer.

28. The method as claimed in claim 17, wherein the first electrode is an anode and the second electrode is a cathode, and wherein the step of forming the second electrode comprises the step of electrically connecting the conductive material layer to the second electrode.

29. The method as claimed in claim 17, wherein the organic light emitting device includes a ground terminal and the terminal having the second voltage is the ground terminal, and the method further comprises the step of electrically connecting the conductive material layers to the ground terminal during or after the formation of the conductive material layers.

30. An organic light emitting device, comprising:
a base part;
first electrode patterns formed on the base part, the first electrode patterns being electrically connected to a first voltage;
pixel defining layers formed between the first electrode patterns to define the first electrode patterns in units of pixels;
conductive material layers formed on the pixel defining layers, the conductive material layers being electrically connected to a terminal having a second voltage lower than the first voltage;
at least one first auxiliary light emitting layer formed on the first electrode patterns, the pixel defining layers, and the conductive material layers;
light emitting layers formed on the first auxiliary light emitting layer, the light emitting layers formed to geometrically correspond to upper parts of the first electrode patterns defined in units of pixels;
at least one second auxiliary light emitting layer formed on the light emitting layers; and
a second electrode formed on the second auxiliary light emitting layer.

31. The organic light emitting device as claimed in claim 30, wherein the first auxiliary light emitting layer includes at least one of a hole injection layer and a hole transport layer.

32. The organic light emitting device as claimed in claim 30, wherein the second auxiliary light emitting layer includes at least one of an electron injection layer and an electron transport layer.

33. The organic light emitting device as claimed in claim 30, wherein the first electrode is an anode and the second electrode is a cathode, and the terminal having the second voltage is the second electrode.

34. The organic light emitting device as claimed in claim 30, wherein the organic light emitting device comprises a ground terminal, and the terminal having the second voltage is the ground terminal.

35. A method of manufacturing an organic light emitting device, the method comprising the steps of:
preparing a base part;
forming first electrode patterns on the base part and electrically connecting the first electrode patterns to a first voltage;
forming pixel defining layers between the first electrode patterns such that the first electrode patterns are defined in units of pixels;
forming conductive material layers on the pixel defining layers and electrically connecting the conductive material layers to a terminal having a second voltage lower than the first voltage;
forming at least one first auxiliary light emitting layer on the first electrode patterns, the pixel defining layers, and the conductive material layers;
forming light emitting layers on the first auxiliary light emitting layer and geometrically corresponding to upper parts of the first electrode patterns defined in units of pixels;
forming at least one second auxiliary light emitting layer on the light emitting layers; and
forming a second electrode on the second auxiliary light emitting layer.

36. The method as claimed in claim 35, wherein the step of forming the first auxiliary light emitting layer comprises at least one of the steps of forming a hole injection layer; and forming a hole transport layer.

37. The method as claimed in claim 34, wherein the step of forming the second auxiliary light emitting layer comprises at least one of the steps of forming an electron injection layer; and forming an electron transport layer.

38. The method as claimed in claim 35, wherein the first electrode is an anode and the second electrode is a cathode, and the step of forming the second electrode comprises the step of electrically connecting the conductive material layers to the second electrode.

39. The method as claimed in claim 35, wherein the organic light emitting device comprises a ground terminal and the terminal having the second voltage is the ground terminal, and the method further comprises the step of electrically connecting the conductive material layers to the ground terminal during or after the step of forming the conductive material layers.
